(19) United States
(12) Patent Application Publication
(10) Pub. No.: US 2024/0405079 A1
(43) Pub. Date: Dec. 5, 2024

(54) IMPLANT SCHEME TO IMPROVE HIGH ELECTRON MOBILITY TRANSISTOR CONTACT RESISTANCE

(71) Applicant: Applied Materials, Inc., Santa Clara, CA (US)

(72) Inventors: Qintao ZHANG, Mt Kisco, NY (US); Michel KHOURY, Palo Alto, CA (US)

(73) Assignee: Applied Materials, Inc., Santa Clara, CA (US)

(21) Appl. No.: 18/327,051

(22) Filed: May 31, 2023

(51) Int. Cl. H01L 29/20; H01L 29/66; H01L 29/778

(52) U.S. Cl. CPC H01L 29/2003; H01L 29/66462; H01L 29/7786

(57) ABSTRACT

Disclosed herein are approaches for creating high electron mobility transistors with reduced contact resistance. In one approach, a method of forming a semiconductor device may include applying a first patterned mask on top of layered stack, wherein the layered stack includes a substrate, a buffer layer disposed over the substrate, a channel layer disposed above the buffer layer, and a barrier layer disposed above the channel layer. The method may further include forming, through an opening of the patterned mask, a source/drain contact in the barrier layer by delivering a first implant to the layered stack, and performing an etch process to form a contact opening in the source/drain contact. The method may further include performing a second implant to the source/drain contact, wherein the second implant is directed into the contact opening.

### FIELD OF THE DISCLOSURE

Embodiments of this disclosure are directed to methods for creating high electron mobility transistors and, more particularly, to implanting high electron mobility transistors to improve contact resistance and uniformity.

### BACKGROUND OF THE DISCLOSURE

High electron mobility transistors (HEMTs) operate based on a difference in band gap between two adjacent layers. In HEMTs, a source contact and a drain contact are disposed on either side of a gate contact. During use, current flows between the source and the drain, depending on the voltage applied to the gate. This is ideally a very low resistance path. However, there are several contributors to the resistance between the source contact and the drain contact. For example, the first is source/drain to channel (2 DEG) tunneling resistance. The second is the bulk resistance through the barrier layer, which may be a AlGaN material. The third is the contact resistance between the source and drain contacts and the barrier layer.

Therefore, it would be beneficial if there were a method of fabricating a HEMT that lowers the overall resistance of the device. It is with respect to these and other drawbacks of the current art that the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method of forming a semiconductor device may include applying a first patterned mask on top of layered stack, wherein the layered stack includes a substrate, a buffer layer disposed over the substrate, a channel layer disposed above the buffer layer, and a barrier layer disposed above the channel layer. The method may further include forming, through an opening of the patterned mask, a source/drain contact in the barrier layer by performing a first implant to the layered stack, and performing an etch process to form a contact opening in the source/drain contact. The method may further include performing a second implant to the source/drain contact, wherein the second implant is directed into the contact opening.

In another aspect, a method of forming a high electron mobility transistor may include applying a first patterned mask on top of layered stack, wherein the layered stack includes a substrate, a buffer layer disposed over the substrate, a channel layer disposed above the buffer layer, and a barrier layer disposed above the channel layer. The method may further include forming, through openings of the patterned mask, a plurality of source/drain contacts in the barrier layer by performing a first implant to the barrier layer and the channel layer, performing an etch process to form a contact opening in each of the plurality of the source/drain contacts, and performing a second implant to the plurality of source/drain contacts, wherein the second implant is directed into the contact openings.

In yet another aspect, a system may include a processor and a memory storing instructions executable by the processor to perform a first implant to a plurality of source/drain contacts formed in a barrier layer of a layered stack, wherein the first implant is performed through a patterned mask formed atop the layered stack, and wherein the layered stack comprises a substrate, a buffer layer disposed over the substrate, a channel layer disposed above the buffer layer, and a barrier layer disposed above the channel layer. The memory may further include instructions executable by the processor to perform a second implant to the plurality of source/drain contacts, wherein the second implant is directed into a contact opening etched into each of the plurality of source/drain contacts.

### BRIEF DESCRIPTION OF THE DRAWINGS

The accompanying drawings illustrate exemplary approaches of the disclosure, including the practical application of the principles thereof, as follows:

FIG. 1 illustrates a cross-sectional side view of a layer stack of an HEMT, according to embodiments of the present disclosure;

FIG. 2 illustrates a cross-sectional side view of a set of openings formed in a masking layer over the HEMT, according to embodiments of the present disclosure;

FIG. 3 illustrates a cross-sectional side view of a first implant performed on the layer stack of the HEMT, according to embodiments of the present disclosure;

FIG. 4 illustrates a cross-sectional side view of the HEMT following formation of a set of contact openings in a source/drain contact, according to embodiments of the present disclosure;

FIG. 5 illustrates a cross-sectional side view of a second implant performed on the layer stack of the HEMT, according to embodiments of the present disclosure;

FIG. 6 illustrates a cross-sectional side view of the HEMT following formation of a gate, a source contact, and a drain contact, according to embodiments of the present disclosure; and

FIG. 7 illustrates a diagram of a processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Devices, transistors, and methods in accordance with the present disclosure will now be described more fully hereinafter with reference to the accompanying drawings, where various embodiments are shown. The devices, transistors, and methods may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art described above, disclosed herein are methods including a Dopant Segregated Schottky (DSS) implant to source/drain (S/D) contacts of a gallium nitride (GaN) high electron mobility transistor (HEMT). The DSS implant may be performed after an initial “top-off” implant, which improves total contact resistance by optimizing both metal to source/drain contact resistance and source/drain to channel resistance. In some embodiments, the top-off implant may be performed following a S/D epitaxy formation through an aluminum GaN layer and a GaN layer, wherein dopants are close to the channel to improve source/drain to channel resistance. The DSS implant may be performed after opening a contact trench, wherein the DSS implant provides a higher doping concentration to improve metal to source/drain contact resistance. As a result, a first resistance in the GaN layer and a second resistance in a metal contact, subsequently formed in the contact trench, are more balanced by increasing implantation dose close to the metal contact without impacting dose proximate the 2DEG.

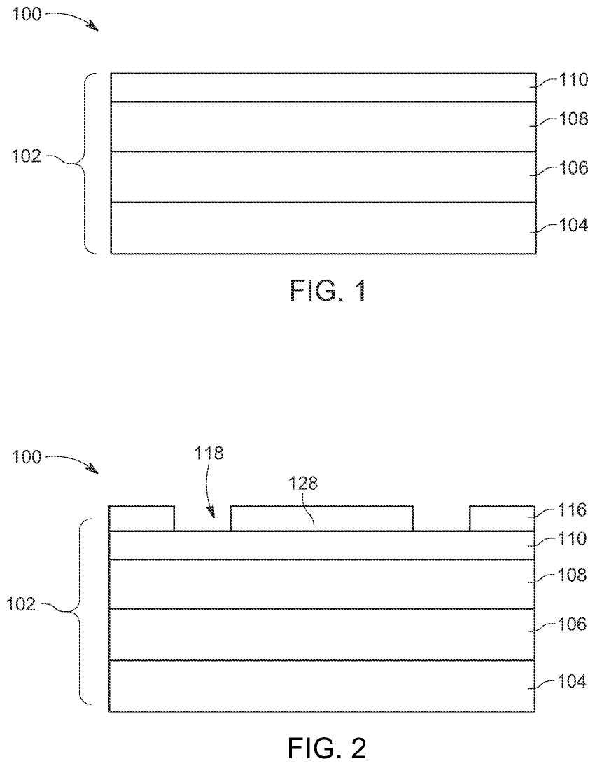

FIG. 1 illustrates a cross-sectional side view of a portion of a semiconductor device 100 (hereinafter “device”), according to embodiments of the present disclosure. In some embodiments, the device 100 may be a HEMT. As shown, the device 100 may include a stack of layers 102 including a substrate 104, a buffer layer 106 disposed over the substrate 104, a channel layer 108 disposed above the buffer layer 106, and a barrier layer 110 disposed above the channel layer 108. The substrate 104 may be suitable for semiconductor epitaxial growth, and may include a group IV semiconductor material such as silicon, for example. Other possible substrate materials include SiC, Sapphire, Si, and bulk GaN.

In some embodiments, the channel layer 106 may comprise a III-V semiconductor material, such as GaN, and the barrier layer 110 may be made of III-V semiconductor materials selected from the group consisting of AlGaN, InAlN, AlN and InAlGaN. Because of their different composition, the barrier layer 110 and the channel layer 108 have different band gaps. Consequently, a two-dimensional electron gas exists in the channel layer 108 near the interface with the barrier layer 110. Although not shown, in some embodiments, a cap layer may be disposed on the barrier layer 110, wherein the cap layer may be GaN or another material. It will be appreciated that each of the layers of the layered stack 102 may be formed by a variety of methods, such as chemical vapor deposition (CVD), low pressure CVD, plasma-enhanced CVD, epitaxially, and others. Furthermore, each layer of the layered stack 102 may be made up of more than one material.

As shown in FIG. 2, a patterned mask 116 (e.g., photoresist) may then be formed over the layered stack 102. In some embodiments, the patterned mask 116 may be formed over the barrier layer 110, and may include a plurality of openings 118 formed therein.

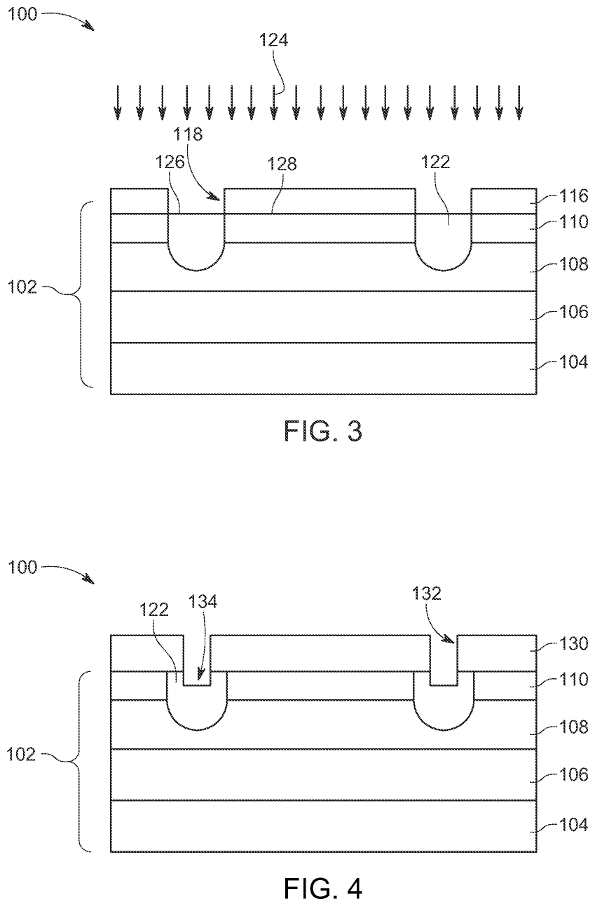

As shown in FIG. 3, a first implant 124 may then be performed to the device 100 to form a plurality of S/D contacts 122 therein. In some embodiments, the S/D contacts 122 may be formed through the openings 118 of the mask 116, wherein a top surface 126 of the S/D contacts 122 may be substantially coplanar with a top surface 128 of the channel layer 108. The first implant 124 may be a top-off implantation process whereby ions are delivered into the layered stack 102 at an energy between 1 KeV and 60 KeV to implant ions to a desired concentration and depth therein. In various embodiments, the ion species of the first implant 124 may be Si, Ge, Nitrogen plus Si and Nitrogen plus Ge. As shown, the patterned mask 116 prevents the first implant 124 from impacting non-desired areas of the layered stack 102. It will be appreciated that the first implant 124 may include a single or multiple implant steps. Furthermore, it will be appreciated that multiple implant steps may be performed at a plurality of different implant energies.

As shown in FIG. 4, a second patterned mask 130 may be formed over the layered stack 102, wherein the second patterned mask 130 includes a set of openings 132 formed therein. In some embodiments, an etch process may then be performed to form a contact opening 134 in each of the S/D contacts 122. As shown, a width of the contact openings 134 may be less than a width of the S/D contacts 122.

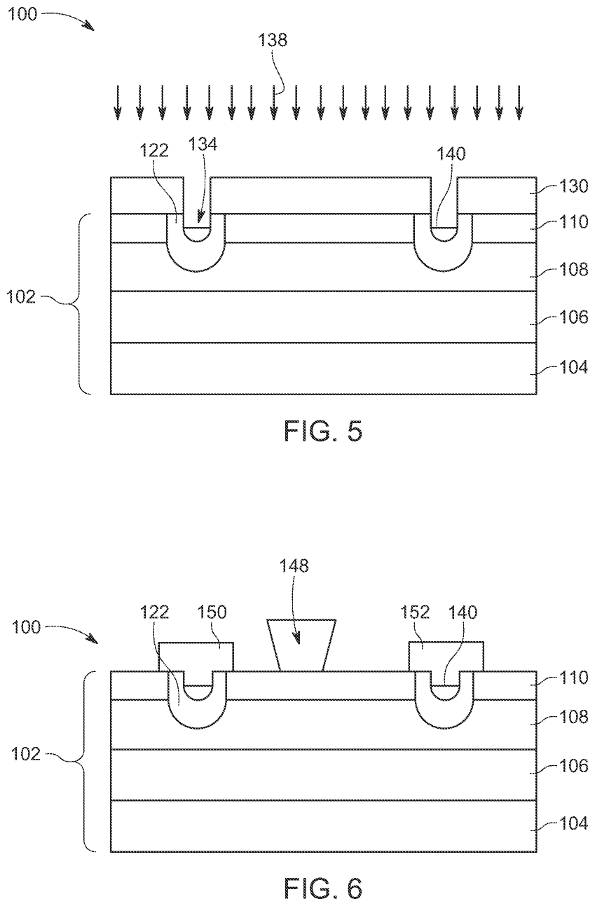

As shown in FIG. 5, a second implant 138 may then be performed. In some embodiments, the second implant 138 may be a DSS implantation process whereby ions are delivered into the S/D contacts 122 at an energy less than 10 KeV to increase doping concentration locally. More specifically, the DSS implant may generate an implanted region 140 in the bottom of each contact opening 134, wherein the implanted region 140 is used to improve resistance between S/D contacts 122 and the barrier layer 110 without impacting source/drain to channel (2 DEG) tunneling resistance, which can be degraded due to high dose induced damages. In various embodiments, the ion species of the second implant 138 may be Si, Ge, Nitrogen plus Si and Nitrogen plus Ge.

The dopant from the second implant 138 and/or the first implant 124 may then be activated, for example, by one or more annealing treatments, and the device 100 may then be further processed, as shown in FIG. 6. In some embodiments, the second patterned mask 130 is removed, and a gate structure 148, a source contact 150, and a drain contact 152 are then formed. In some embodiments, the gate structure 148 is formed over the barrier layer 110. In certain embodiments, the gate structure 148 may include a metal, such as Ti, Al, TiN, W, WN, Ni, Au, Pt, polysilicon, and any other suitable conductive material. To form the gate structure 148, a set of layers may be disposed over the top surface of the barrier layer 110, and the material used for the gate structure 148 may be deposited. A lithography process may be used to pattern the gate to form the shape of gate structure 148.

The source contact 150 and the drain contact 152 may be formed in the contact openings 134 of the layered stack 102. This may be performed using conventional methods. For example, a conductive material, such as a metal, may be disposed on the surface of the workpiece. The conductive material fills the contact openings 134. In this way, the conductive material is in contact with the barrier layer 110, the S/D contacts 122 and the implanted region 140. The conductive material of the source contact 150 and the drain contact 152 may be Ti, Al, TiN, W, WN, Ni, Au, or Pt, or any other suitable conductive material.

It will be appreciated that some of the fabrication processes described herein may be performed in a different order. For example, a gate first process may be performed, where the gate structure 148 is added before the source contact 150 and the drain contact 152 have been formed in the layered stack 102.

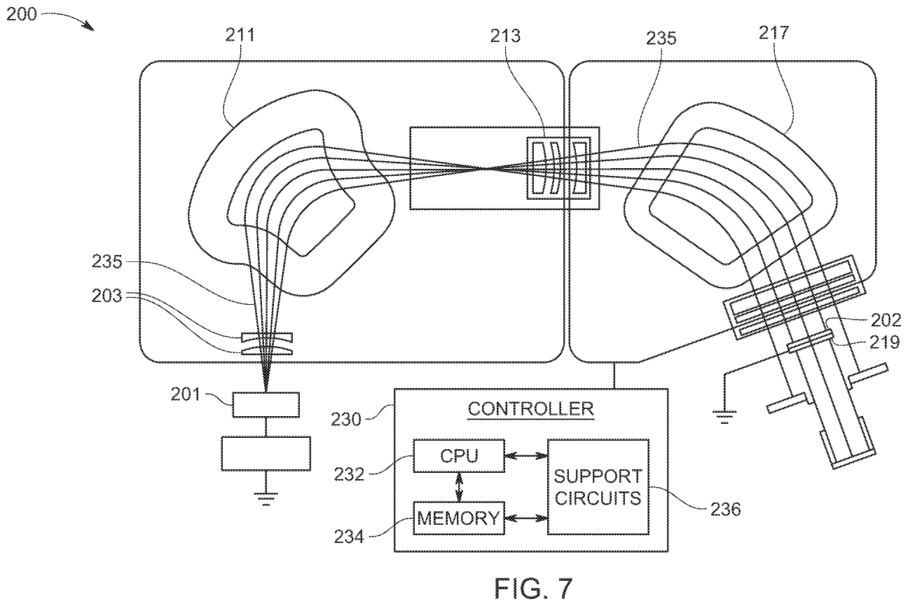

FIG. 7 illustrates a schematic diagram of a processing apparatus 200 useful to perform processes described herein. One example of a beam-line ion implantation processing apparatus is the Varian VIISTA® Trident, available from Applied Materials Inc., Santa Clara, CA. The processing apparatus 200 may include an ion source 201 for generating ions. For example, the ion source 201 may provide an ion implant, such as the first implant 124 demonstrated in FIG. 3 and the second implant 138 demonstrated in FIG. 5. The ion source 201 is operable to perform the first implant 124 and the second implant 138 at an implant energy between 1 KeV and 60 KeV, an implant dose between 1e14/cm2 and 1e16/cm2, and at an implant temperature between −100° C. and 500° C.

The processing apparatus 200 may also include a series of beam-line components. Examples of beam-line components may include extraction electrodes 203, a magnetic mass analyzer 211, a plurality of lenses 213, and a beam parallelizer 217. The processing apparatus 200 may also include a platen 219 for supporting a substrate 202 to be processed. The substrate 202 may be the same as the substrate 104 described above. The substrate 202 may be moved in one or more dimensions (e.g., translate, rotate, tilt, etc.) by a platform component sometimes referred to as a “roplat” (not shown). It is also contemplated that the platen 219 may be configured to perform the heated and/or cooled implantation processes described herein with respect to the first implant 124 and the second implant 138.

In operation, ions of the desired species, for example, dopant ions, are generated and extracted from the ion source 201. Thereafter, the extracted ions 235 travel in a beam-like state along the beam-line components and may be implanted in the substrate 202. Similar to a series of optical lenses that manipulate a light beam, the beam-line components manipulate the extracted ions 235 along the ion beam. In such a manner, the extracted ions 235 are manipulated by the beam-line components while the extracted ions 235 are directed toward the substrate 202. It is contemplated that the apparatus 200 may provide for improved mass selection to implant desired ions while reducing the probability of undesirable ions (impurities) being implanted in the substrate 202.

In some embodiments, the processing apparatus 200 can be controlled by a processor-based system controller such as controller 230. For example, the controller 230 may be configured to control beam-line components and processing parameters associated with beam-line ion implantation processes. The controller 230 may include a programmable central processing unit (CPU) 232 that is operable with a memory 234 and a mass storage device, an input control unit, and a display unit (not shown), such as power supplies, clocks, cache, input/output (I/O) circuits, and the like, coupled to the various components of the processing apparatus 200 to facilitate control of the substrate processing. The controller 230 also includes hardware for monitoring substrate processing through sensors in the processing apparatus 200, including sensors monitoring the substrate position and sensors configured to receive feedback from and control a heating apparatus coupled to the processing apparatus 200. Other sensors that measure system parameters such as substrate temperature and the like, may also provide information to the controller 230.

To facilitate control of the processing apparatus 200 described above, the CPU 232 may be one of any form of general-purpose computer processor that can be used in an industrial setting, such as a programmable logic controller (PLC), for controlling various chambers and sub-processors. The memory 234 is coupled to the CPU 232 and the memory 234 is non-transitory and may be one or more of readily available memory such as random access memory (RAM), read only memory (ROM), floppy disk drive, hard disk, or any other form of digital storage, local or remote. Support circuits 236 may be coupled to the CPU 232 for supporting the processor in a conventional manner. Implantation and other processes are generally stored in the memory 234, typically as a software routine. The software routine may also be stored and/or executed by a second CPU (not shown) that is remotely located from the hardware being controlled by the CPU 232.

The memory 234 is in the form of computer-readable storage media that contains instructions, that when executed by the CPU 232, facilitates the operation of the apparatus 200. The instructions in the memory 234 are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

As used herein, “depositing” and/or “deposited” may include any now known or later developed techniques appropriate for the material to be deposited including yet not limited to, for example: chemical vapor deposition (CVD), low-pressure CVD (LPCVD), and plasma-enhanced CVD (PECVD). Additional techniques may include semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method of forming a semiconductor device, comprising:
applying a first patterned mask on top of layered stack, wherein the layered stack comprises:
a substrate,
a buffer layer disposed over the substrate;
a channel layer disposed above the buffer layer; and
a barrier layer disposed above the channel layer;
performing a first implant to the layered stack to form a source/drain contact in the barrier layer;
performing an etch process to form a contact opening in the source/drain contact; and
performing a second implant to the source/drain contact, wherein the second implant is directed into the contact opening.

2. The method of claim 1, further comprising applying a second patterned mask on top of layered stack, wherein the etch process and the second implant are performed through the second patterned mask.

3. The method of claim 1, wherein the channel layer is gallium nitride.

4. The method of claim 1, wherein the barrier layer is aluminum gallium nitride.

5. The method of claim 1, wherein a first implant energy of the first implant is greater than a second implant energy of the second implant.

6. The method of claim 1, wherein an ion species of the first implant and the second implant is silicon, germanium, nitrogen plus silicon, or nitrogen plus germanium.

7. The method of claim 1, further comprising forming a gate, and a source contact and a drain contact over the layered stack, wherein the source contact in the drain contact formed in the contact openings.

8. A method of forming a high electron mobility transistor, comprising:
applying a first patterned mask on top of layered stack, wherein the layered stack comprises:
a substrate,
a buffer layer disposed over the substrate;
a channel layer disposed above the buffer layer; and
a barrier layer disposed above the channel layer;
forming, through openings of the patterned mask, a plurality of source/drain contacts in the barrier layer by delivering a first implant into the barrier layer and the channel layer;
performing an etch process to form a contact opening in each of the plurality of the source/drain contacts; and
performing a second implant to the plurality of source/drain contacts, wherein the second implant is directed into the contact openings.

9. The method of claim 8, further comprising applying a second patterned mask on top of layered stack, wherein the etch process and the second implant are performed through the second patterned mask.

10. The method of claim 8, wherein the channel layer is gallium nitride, and wherein the barrier layer is aluminum gallium nitride.

11. The method of claim 8, wherein a first implant energy of the first implant is greater than a second implant energy of the second implant.

12. The method of claim 8, an ion species of the first implant and the second implant is silicon, germanium, nitrogen plus silicon, or nitrogen plus germanium.

13. The method of claim 8, further comprising forming a gate, and a source contact and a drain contact over the layered stack, wherein the source contact in the drain contact are formed in the contact openings.

14. A system, comprising:
a processor;
a memory storing instructions executable by the processor to:
perform a first implant to a layered stack to form a plurality of source/drain contacts, wherein the first implant is performed through a patterned mask formed atop the layered stack, wherein the layered stack comprises a substrate, a buffer layer disposed over the substrate, a channel layer disposed above a buffer layer, and a barrier layer disposed above the channel layer; and
perform a second implant to the plurality of source/drain contacts, wherein the second implant is directed into a contact opening etched into each of the plurality of source/drain contacts.

15. The system of claim 14, the memory further storing instructions executable by the processor to apply a second patterned mask on top of layered stack, wherein the contact opening is etched and the second implant is performed through the second patterned mask.

16. The system of claim 14, wherein the channel layer is gallium nitride, and wherein the barrier layer is aluminum gallium nitride.

17. The system of claim 14, wherein a first implant energy of the first implant is greater than a second implant energy of the second implant.

18. The system of claim 14, an ion species of the first implant and the second implant is silicon, germanium, nitrogen plus silicon, or nitrogen plus germanium.

19. The system of claim 14, the memory further storing instructions executable by the processor to:
form a gate atop the layered stack; and
form a source contact and a drain contact over the layered stack, adjacent the gate.
